(19) United States
(12) Patent Application Publication
(10) Pub. No.: US 2014/0126124 A1
(43) Pub. Date: May 8, 2014

(54) TOUCH DEVICE

(71) Applicant: HENGHAO TECHNOLOGY CO. LTD, Taoyuan County (TW)

(72) Inventors: CHEN-CHANG HSU, Taichung City (TW); Yung-Chih Liu, Taichung City (TW); Chin-Liang Chen, Kaohsiung City (TW); Ting-Chieh Chen, Taoyuan County (TW)

(73) Assignee: HENGHAO TECHNOLOGY CO. LTD, Taoyuan County (TW)

(21) Appl. No.: 13/728,938

(22) Filed: Dec. 27, 2012

(30) Foreign Application Priority Data
Nov. 7, 2012 (TW) 101141293

(51) Int. Cl. H05K 5/00

(52) U.S. Cl. CPC H05K 5/0004
USPC 361/679.01

(57) ABSTRACT

A touch device includes a top housing and bottom housing, which define an accommodating space. A touch panel has a lateral surface abutting the top housing. A hollow frame crosses adjacency between a top surface of the touch panel and a top surface of the top housing.

### CROSS-REFERENCE TO RELATED APPLICATIONS

The entire contents of Taiwan Patent Application No. 101141293, filed on Nov. 7, 2012, from which this application claims priority, are incorporated herein by reference.

### BACKGROUND OF THE INVENTION

1. FIELD OF THE INVENTION

The present invention generally relates to a touch device, and more particularly to a touch device with a hollow frame.

2. DESCRIPTION OF RELATED ART

A touch screen is an input/output device that adopts sensing technology and display technology, and has been widely employed in electronic devices such as portable or hand-held electronic devices.

A capacitor-based touch panel is a commonly used touch panel that utilizes capacitive coupling effect to detect touch position. Specifically, capacitance corresponding to the touch position. changes and is thus detected, when a finger touches a surface of the touch panel.

FIG. 1 shows a cross-sectional view of a conventional touch device 1, which includes a top housing 11 and a bottom housing 12. Disposed in a space defined by the top housing 11 and the bottom housing 12 are, from the bottom upward, a liquid crystal (display) module (LCM) 13, a touch panel (TP) 14 and a protective film 15. As shown in FIG. 1, an inward extended portion 110 of the top housing of the conventional touch device 1 should have a proper thickness in order to ensure adequate strength. The thickness of the inward extended portion 110, however, forms a vertical drop between a top surface of the top housing 11 and a top surface of the protective film 15, and results in discomfort for users. Moreover, as the protective film 15 of the conventional touch device 1 covers an entire top surface of the touch panel 14, the touch device 1 therefore has lower transmittance, brightness, contrast and touch sensitivity.

FIG. 2 shows a cross-sectional view of another conventional touch device 2, which includes a top housing 21 and a bottom housing 22. Disposed in a space defined by the top housing 21 and the bottom housing 22 are, from the bottom upward, a liquid. crystal module (LCM) 23 and a touch panel 24. Specifically, the touch panel 24 includes, from the top downward, a glass substrate 241, a black matrix (BM) 242 and a touch sensing layer 243. As the yield of the black matrix 242 is commonly not high enough, the cost of manufacturing the touch device 2 therefore cannot be considerably cut down.

For the reasons that conventional touch devices are uncomfortable to operate, and are low in transmittance and yield, a need has this arisen to propose a novel touch device to overcome deficiencies of the conventional touch devices.

### SUMMARY OF THE INVENTION

In view of the foregoing, it is an object of the embodiment of the present invention to provide a touch device with a hollow frame covering a touch panel and a top housing, but without a black matrix, therefore substantially improving operating comfort, transmittance, yield or typesetting.

According to one embodiment, a touch device includes a top housing, a bottom housing, a touch panel and a hollow frame. The top housing and the bottom housing define an accommodating space. The touch panel has a lateral surface abutting the top housing. The hollow frame crosses adjacency between a top surface of the touch panel and a top surface of the top housing.

### BRIEF DESCRIPTION OF THE DRAWINGS

FIG. 1 shows a cross-sectional view of a conventional touch device;

FIG. 2 shows a cross-sectional view of another conventional touch device;

FIG. 3A shows a cross-sectional view of a touch device according to one embodiment of the present invention;

FIG. 3B shows a top view of the touch device of FIG. 3A; and

FIG. 4 shows a detailed cross-sectional view of the touch panel of FIG. 3A.

### DETAILED DESCRIPTION OF THE INVENTION

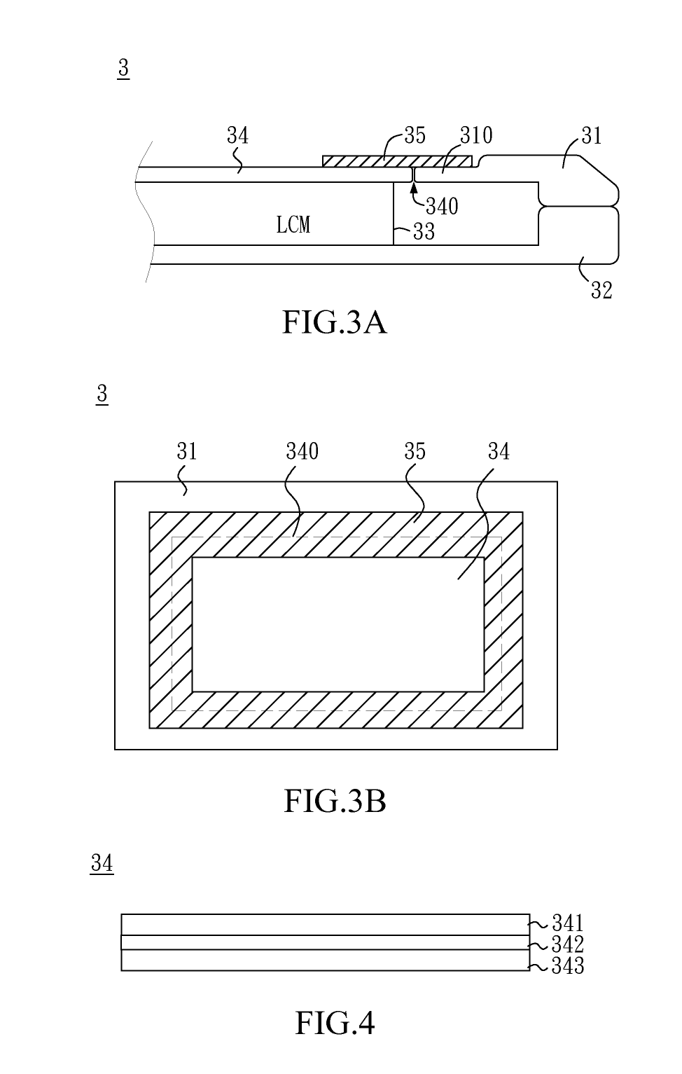

FIG. 3A shows a cross-sectional view of a touch device 3 according to one embodiment of the present invention, and FIG. 3B shows a top view of the touch device 3 of FIG. 3A. In the embodiment, the touch device 3 includes a top housing 31 and a bottom housing 32. In the specification, the direction “top” points to a touch surface of the touch device 3, and the direction “bottom” points against the touch surface of the touch device 3. The top housing 31 and the bottom housing 32 define a space for accommodating a display module 33 (e.g., a liquid crystal module (LCM)) or other circuits (e.g., a power circuit (not shown)). The display module 33 of the embodiment may adopt display architectures that are currently available or to be developed in the future.

The touch device 3 also includes a touch panel (TP) 34, e.g., a capacitor-based. touch panel, disposed above the display module 33. The touch panel 34 has a lateral surface abutting the top housing 31. As exemplified in FIG. 3A/3B, the lateral surface of the touch panel 34 abuts an inward extended portion 310 of the top housing at adjacency 340. A top surface of the touch panel 34 is substantially level with at least a partial top surface of the top housing 31 (e.g., a top surface of the inward extended portion 310).

The touch panel 34 of the embodiment may adopt touch architectures that are currently available or to be developed in the future. In one embodiment, as shown in a cross-sectional view of the touch panel 34 of FIG. 4, the touch panel 34 includes, from the top downward, a transparent substrate 341, and a touch sensing layer 342 coated on a bottom surface of the transparent substrate 341. The touch panel 34 made of the transparent substrate 341 and the touch sensing layer 342 may be called a one-glass-solution (OGS) touch panel 34. In one embodiment, a cover layer 343 may be further disposed below the touch sensing layer 342. The transparent substrate 341 and the cover layer 343 mentioned above may include insulating material of high transmittance such as glass, Polycarbonate (PC), Polyethylene terephthalate (PET), Polymethyl methacrylate (PMMA) or Cyclic olefin copolymer (COC). The touch sensing layer 342 may include transparent conductive material such as Indium tin oxide (ITO) or Indium zinc oxide (IZO).

According to one aspect of the embodiment, the touch device 3 includes a frame 35 that crosses the adjacency 340 between the top surface of the touch panel 34 and the top surface of the top housing 31. The frame 35 may be formed by printing, coating or other suitable techniques. The frame 35 of the embodiment is a hollow frame with a closed or open frame border. The hollow frame may include Polyethylene terephthalate (PET), Polycarbonate (PC), Polymethyl methacrylate (PMMA) or other insulating materials. In one embodiment, the hollow frame 35 acts as a decoration film with required colors and patterns by introducing colors therein. In the embodiment, an area of the touch panel 34 covered, by the hollow frame 35 (e.g., below the frame border of the hollow frame 35) may be utilized as a tracing portion, and an area of the touch panel 34 not covered by the hollow frame 35 (e.g., below the hollow portion of the hollow frame 35) may be utilized, as a sensing portion.

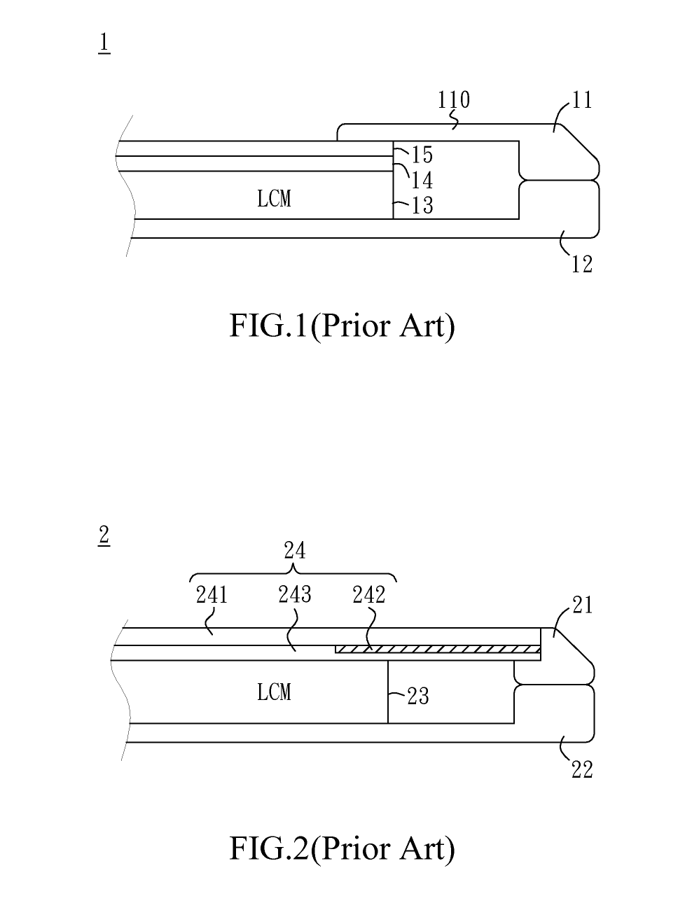

Compared with the conventional touch devices, the embodiment has at least the following aspects. As the hollow frame 35 of the embodiment has an inner empty area, it precludes lower transmittance encountered in the conventional touch device (e.g., 1 of FIG. 1) due to overall coverage of the touch panel. Further, as the frame border of the hollow frame 35 serves to shield, the tracing portion of the touch panel 34, the black matrix (e.g., 242 of FIG. 2) adapted in the conventional touch device may thus be omitted, thereby improving yield and typesetting. Moreover, as a partial top surface of the top housing 31 of the embodiment may be substantially level with the top surface of the touch panel 34 and the hollow frame 35 may commonly be made thin enough, it precludes discomfort for users encountered in the conventional touch device (e.g., 1 of FIG. 1) due to the vertical drop between the top surface of the top housing and the top surface of the touch panel. In addition, in the embodiment, the typesetting (i.e., an amount of the touch panels 34 that may be arranged and cut on one transparent substrate 341) may be larger than the typesetting of the conventional touch device (e.g., 2 of FIG. 2).

Although specific embodiments have been illustrated and described, it will be appreciated. by those skilled in the art that various modifications may be made without departing from the scope of the present invention, which is intended to be limited solely by the appended claims.

What is claimed is:

1. A touch device, comprising:
a top housing and a bottom housing, which define an accommodating space;
a touch panel having a lateral surface abutting the top housing; and
a hollow frame crossing adjacency between a top surface of the touch panel and a top surface of the top housing.

2. The touch device of claim 1, wherein the top housing comprises an inward extended portion abutting the lateral surface of the touch panel at the adjacency.

3. The touch device of claim 2, wherein the top surface of the touch panel is substantially level with a top surface of the inward extended portion.

4. The touch device of claim 1, further comprising a display module disposed in the accommodating space and below the touch panel.

5. The touch device of claim 1, wherein the touch panel comprises:
a transparent substrate; and
a touch sensing layer disposed below the transparent substrate.

6. The touch device of claim 5, wherein the touch sensing layer comprises transparent conductive material.

7. The touch device of claim 5, wherein the touch panel further comprises a cover layer disposed below the touch sensing layer.

8. The touch device of claim 7 wherein the transparent substrate or the cover layer comprises transparent insulating material.

9. The touch device of claim 8, wherein, the transparent insulating material comprises glass, Polycarbonate (PC), Polyethylene terephthalate (PET), Polymethyl methacrylate (PMMA) or Cyclic olefin copolymer (COC).

10. The touch device of claim 1, wherein the hollow frame comprises Polyethylene terephthalate (PET), Polycarbonate (PC) or Polymethyl methacrylate (PMMA).

11. The touch device of claim 1, wherein an area of the touch panel covered by the hollow frame is defined, as a tracing portion, and an area of the touch panel not covered by the hollow frame is defined as a sensing portion.
